(19) United States
(12) Patent Application Publication
(10) Pub. No.: US 2016/0232957 A1
(43) Pub. Date: Aug. 11, 2016

(54) SEMICONDUCTOR MEMORY APPARATUS AND OPERATING METHOD OF SEMICONDUCTOR SYSTEM USING THE SAME

(71) Applicant: SK hynix Inc., Icheon-si Gyeonggi-do (KR)

(72) Inventors: Soo Young JANG, Icheon-si Gyeonggi-do (KR); Hyun Woo LEE, Icheon-si Gyeonggi-do (KR)

(21) Appl. No.: 14/729,528

(22) Filed: Jun. 3, 2015

(30) Foreign Application Priority Data
Feb. 10, 2015 (KR) 10-2015-0020454

(51) Int. Cl. G11C 8/10; G11C 7/10; G11C 8/06; G11C 8/08; G11C 8/12; G11C 8/18; G11C 7/06; G11C 7/12

(52) U.S. Cl. CPC G11C 8/10; G11C 7/06; G11C 7/10; G11C 7/12; G11C 8/08; G11C 8/12; G11C 8/18; G11C 8/06

(57) ABSTRACT

A semiconductor memory apparatus includes an address determination block configured to output an address as one of a row address and a column address according to an internal command; a row address decoding block configured to decode the row address and enable a word line; a column address decoding block configured to decode a partial column address of the column address and enable a column select signal; a data select signal generation block configured to enable a data select signal according to the row address and a remaining column address of the column address; and a data storage region configured to store or output data according to the word line, the column select signal and the data select signal.

### CROSS-REFERENCES TO RELATED APPLICATION

The present application claims priority under 35 U.S.C. §119(a) to Korean application number 10-2015-0020454, filed on Feb. 10, 2015, in the Korean Intellectual Property Office, which is incorporated herein by reference in its entirety.

### BACKGROUND

1. Technical Field

Various embodiments generally relate to a semiconductor integrated circuit, and more particularly, to a semiconductor memory apparatus and an operating method of a semiconductor system using the same.

2. Related Art

A general semiconductor memory apparatus is configured to activate one of a plurality of banks and output data from the activated bank or store data in the activated bank. Thereafter, a read operation or a write operation is completed by precharging data output paths or data output pads when data are outputted or stored.

Therefore, the general semiconductor memory apparatus is configured to sequentially perform active, read or write and precharge operations. That is to say, in order to store or output one data, the semiconductor memory apparatus should sequentially perform active, read or write and precharge operations, and, in order to store or output two data, the semiconductor memory apparatus should sequentially perform active, read or write, precharge, active, read or write and precharge operations.

Such an operation pattern of the semiconductor memory apparatus serves as a problem in a technology for increasing the data input/output speed of the semiconductor memory apparatus.

### SUMMARY

In an embodiment, a semiconductor memory apparatus may include an address determination block configured to output an address as one of a row address and a column address according to an internal command. The semiconductor memory apparatus may also include a row address decoding block configured to decode the row address and enable a word line. The semiconductor memory apparatus may also include a column address decoding block configured to decode a partial column address of the column address and enable a column select signal. The semiconductor memory apparatus may also include a data select signal generation block configured to enable a data select signal according to the row address and a remaining column address of the column address. Further, the semiconductor memory apparatus may also include a data storage region configured to store or output data according to the word line, the column select signal and the data select signal.

In an embodiment, an operating method of a semiconductor system including a controller which provides a command and an address and provides data or is inputted with the data. Further, a semiconductor memory apparatus which stores provided data or outputs stored data in response to the command and the address. The operating method includes an active command providing action in which the controller consecutively provides a plurality of active commands to the semiconductor memory apparatus. The operating method also includes an operation command providing action in which the controller consecutively provides a plurality of read or write commands to the semiconductor memory apparatus. Further, the operating method includes a precharge command providing action in which the controller provides a precharge command to the semiconductor memory apparatus.

In an embodiment, a semiconductor memory apparatus may include a row address decoding block configured to enable together a plurality of word lines according to a row address. The semiconductor memory apparatus may also include a column address decoding block configured to decode a part of a column address and generate a column select signal. The semiconductor memory apparatus may also include a data select signal generation block configured to generate a data select signal according to the row address and a remainder of the column address. Further, the semiconductor memory apparatus may also include a data storage region configured to selectively output a plurality of data selected by the plurality of word lines enabled together and the column select signal enabled according to the data select signal.

### BRIEF DESCRIPTION OF THE DRAWINGS

FIG. 1 is a configuration diagram illustrating a representation of an example of a semiconductor system in accordance with an embodiment.

FIG. 2 is a configuration diagram illustrating a representation of an example of the semiconductor memory apparatus in accordance with an embodiment.

FIG. 3 is a configuration diagram illustrating a representation of an example of the data storage region shown in FIG. 2.

FIG. 4 is a configuration diagram illustrating a representation of an example of the row address decoding block shown in FIG. 2.

FIG. 5 is a configuration diagram illustrating a representation of an example of the data select signal generation block shown in FIG. 2.

### DETAILED DESCRIPTION

Hereinafter, a semiconductor memory apparatus and an operating method of a semiconductor system using the same will be described below with reference to the accompanying figures through embodiments.

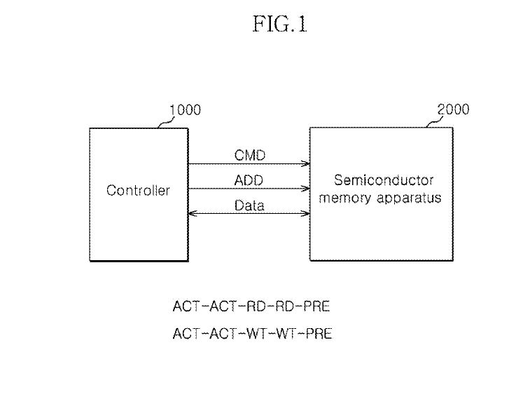

Referring to FIG. 1, a semiconductor system in accordance with an embodiment includes a controller 1000 and a semiconductor memory apparatus 2000.

The controller 1000 provides a command CMD, an address ADD and data DATA to the semiconductor memory apparatus 2000 or is provided with data DATA from the semiconductor memory apparatus 2000.

The semiconductor memory apparatus 2000 is provided with the command CMD, the address ADD and the data DATA from the controller 1000 or provides the data DATA according to the command CMD and the address ADD to the controller 1000. For example, the semiconductor memory apparatus 2000 performs a specified operation (for example, a read or write operation) according to the command CMD at the position designated by the address ADD. In detail, the semiconductor memory apparatus 2000 stores the data DATA at the position designated by the address ADD according to the command CMD. In the alternative, the semiconductor memory apparatus 2000 outputs the data DATA from the position designated by the address ADD according to the command CMD. The controller 1000 provides the address ADD each time of providing one command CMD to the semiconductor memory apparatus 2000.

In the semiconductor system in accordance with an embodiment, configured as mentioned above, after the controller 1000 consecutively provides an active command ACT to the semiconductor memory apparatus 2000, a read command RD or a write command WT may be consecutively provided. Further, a precharge command PRE may then be provided. As shown in FIG. 1, consecutive two active commands ACT-ACT, consecutive two read commands RD-RD or consecutive two write commands WT-WT and one precharge command PRE may be provided from the controller 1000 to the semiconductor memory apparatus 2000.

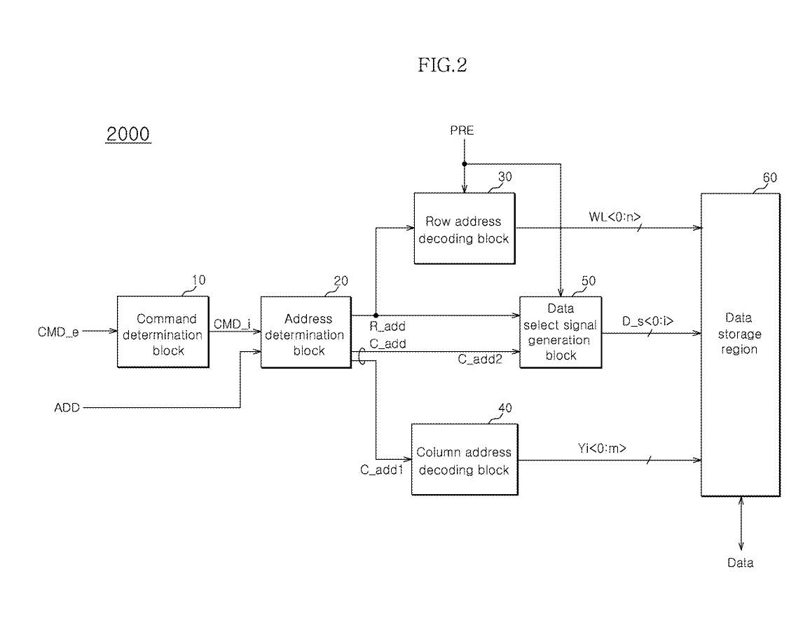

Referring to FIG. 2, the semiconductor memory apparatus 2000 includes a command determination block 10, an address determination block 20, a row address decoding block 30, a column address decoding block 40, a data select signal generation block 50, and a data storage region 60.

The command determination block 10 determines an external command CMD_e provided from the controller 1000 and generates an internal command CMD_i. In FIG. 2, in order to distinguish a command provided from an exterior of the semiconductor memory apparatus 2000 and a command generated internally of the semiconductor memory apparatus 2000 according to the command provided from the exterior, the command provided from the controller 1000 is explained as the external command CMD_e. Further, the command generated internally of the semiconductor memory apparatus 2000 is explained as the internal command CMD_i.

The address determination block 20 outputs the address ADD provided from the controller 1000, as one of a row address R_add and a column address C_add, in response to the internal command CMD_i. For example, the address determination block 20 outputs the address ADD as the row address R_add when the internal command CMD_i is an active command. The address determination block 20 outputs the address ADD as the column address C_add when the internal command CMD_i is a read command or a write command.

The row address decoding block 30 selectively enables word lines WL<0:n> in response to the row address R_add. The row address decoding block 30 retains the enabled word lines WL<0:n> until a precharge signal PRE is enabled. Therefore, since the row address decoding block 30 does not disable the enabled word lines WL<0:n> until the precharge signal PRE is enabled, the plurality of word lines WL<0:n> may be enabled together by enabling the word lines WL<0:n> one by one each time the row address R_add is inputted.

The column address decoding block 40 decodes a part C_add1 of the column address C_add and selectively enables column select signals Yi<0:m>. For example, the column address decoding block 40 decodes the part C_add1 of the column address C_add. Further, the column address decoding block 40 also enables one of the column select signals Yi<0:m>.

The data select signal generation block 50 generates data select signals D_s<0:i> in response to the row address R_add and a remainder C_add2 of the column address C_add. For example, the data select signal generation block 50 latches the row address R_add which is consecutively inputted. In addition, the data select signal generation block 50 outputs one of latched signals as the data select signal D_s<0:i> which is enabled, in response to the remainder C_add2 of the column address C_add. In other words, the data select signal generation block 50 stores positions where data DATA are to be stored or outputted by the word lines WL<0:n> enabled together, by latching the row address R_add. The data select signal generation block 50 also generates the data select signals D_s<0:i> such that one among the stored positions may be selected according to the remainder C_add2 of the column address C_add.

The data storage region 60 stores or outputs data DATA in response to the word lines WL<0:n>, the column select signals Yi<0:m> and the data select signals D_s<0:i>. For example, the data storage region 60 primarily selects positions where data DATA are to be stored or outputted, by the word lines WL<0:n> enabled together and the column select signals Yi<0:m> enabled. Further, the data storage region 60 secondarily selects one position among the primarily selected positions in response to the data select signals D_s<0:i> enabled. Data DATA are stored or outputted in or from the secondarily selected position of the data storage region 60.

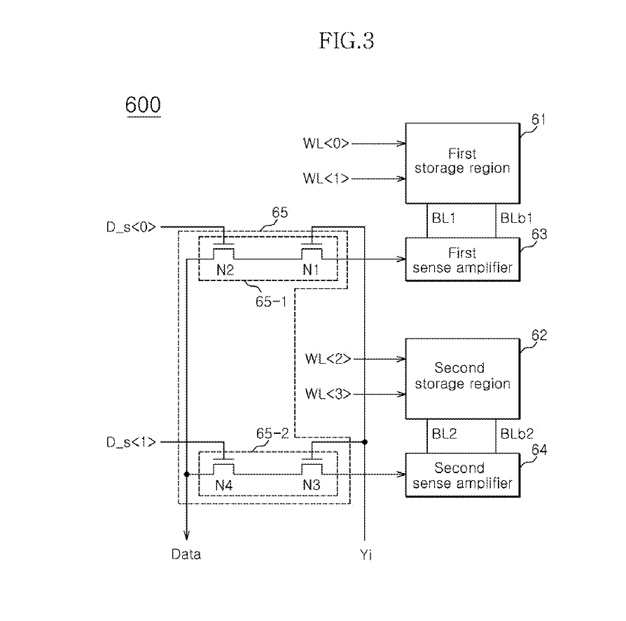

Referring to FIG. 3, a data storage region 600 (an embodiment of the data storage region 60 shown in FIG. 2) may include a first storage region 61, a second storage region 62, a first sense amplifier 63, a second sense amplifier 64, and a data selection unit 65.

The first storage region 61 is a configuration capable of storing or outputting data DATA when it is activated. The first storage region 61 is activated when even one of a first word line WL<0> and a second word line WL<1> is enabled. For example, the first storage region 61 may store or output data DATA in or from a position to which the first word line WL<0> corresponds, when the first word line WL<0> is enabled. Further, the first storage region 61 may store or output data DATA in or from a position to which the second word line WL<1> corresponds, when the second word line WL<1> is enabled.

The second storage region 62 is a configuration capable of storing or outputting data DATA when it is activated. The second storage region 62 is activated when even one of a third word line WL<2> and a fourth word line WL<3> is enabled. For example, the second storage region 62 may store or output data DATA in or from a position to which the third word line WL<2> corresponds, when the third word line WL<2> is enabled. The second storage region 62 may also store or output data DATA in or from a position to which the fourth word line WL<3> corresponds, when the fourth word line WL<3> is enabled.

The first sense amplifier 63 is electrically coupled with the first storage region 61 through a first bit line BL1 and a first bit line bar BLb1. For example, when the first storage region 61 is activated, the first sense amplifier 63 senses and amplifies the data DATA transferred through the first bit line BL1 and the first bit line bar BLb1. In the alternative, the first storage region 61 transfers data DATA to the activated first storage region 61.

The second sense amplifier 64 is electrically coupled with the second storage region 62 through a second bit line BL2 and a second bit line bar BLb2. For example, when the second storage region 62 is activated, the second sense amplifier 64 senses and amplifies the data DATA transferred through the second bit line BL2 and the second bit line bar BLb2. Alternatively, the second storage region 62 transfers data DATA to the activated second storage region 62.

The data selection unit 65 transfers or is transferred with data DATA to or from one of the first sense amplifier 63 and the second sense amplifier 64 in response to the column select signal Yi and the first and second data select signals D_s<0:1>. For example, the data selection unit 65 transfers or is transferred with data DATA to or from the first sense amplifier 63 when the column select signal Yi is enabled and the first data select signal D_s<0> is enabled. The data selection unit 65 transfers or is transferred with data DATA to or from the second sense amplifier 64 when the column select signal Yi is enabled and the second data select signal D_s<1> is enabled.

The data selection unit 65 includes a first data selection section 65-1 and a second data selection section 65-2.

The first data selection section 65-1 transfers or is transferred with data DATA to or from the first sense amplifier 63 when the column select signal Yi is enabled and the first data select signal D_s<0> is enabled.

The first data selection section 65-1 includes first and second transistors N1 and N2 as switches. The first transistor N1 has the gate which is inputted with the column select signal Yi. Further, the drain and the source to which the first sense amplifier 63 and the second transistor N2 are respectively electrically coupled. The second transistor N2 has the gate inputted with the first data select signal D_s<0>. Further, the drain and the source to one of which the first transistor N1 is electrically coupled and to or from the other of which data DATA is inputted or outputted.

The second data selection section 65-2 transfers or is transferred with data DATA to or from the second sense amplifier 64 when the column select signal Yi is enabled and the second data select signal D_s<1> is enabled.

The second data selection section 65-2 includes third and fourth transistors N3 and N4 as switches. The third transistor N3 has the gate inputted with the column select signal Yi. In addition, the drain and the source to which the second sense amplifier 64 and the fourth transistor N4 are respectively electrically coupled. The fourth transistor N4 has the gate inputted with the second data select signal D_s<1>. Further, the drain and the source to one of which the third transistor N3 is electrically coupled and to or from the other of which data DATA is inputted or outputted.

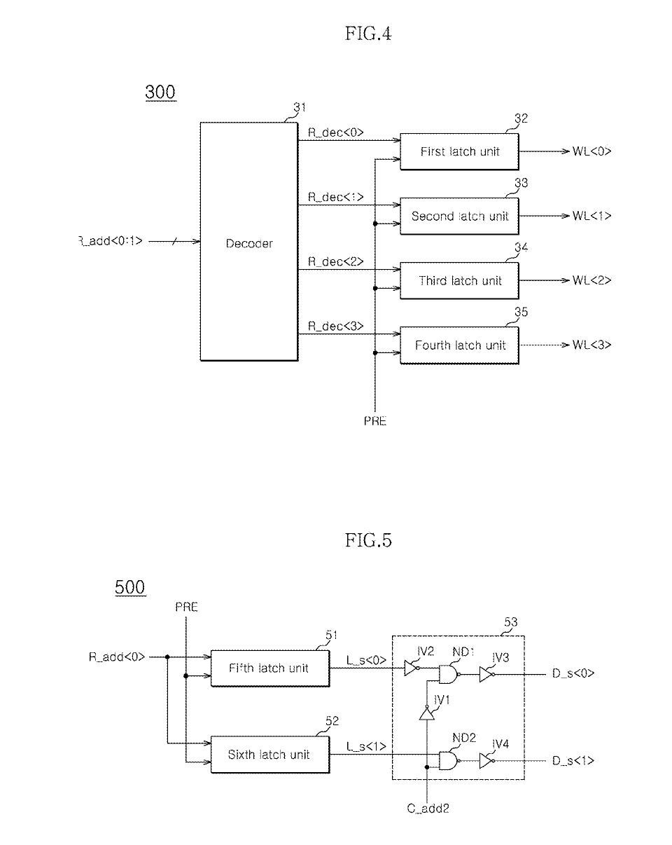

Referring to FIG. 4, a row address decoding block 300 (an embodiment of the row address decoding block 30 shown in FIG. 2), which generates signals for the first to fourth word lines WL<0:3> to activate the first and second storage regions 61 and 62, includes a decoder 31 and first to fourth latch units 32, 33, 34 and 35.

The decoder 31 decodes a first row address R_add<0> and a second row address R_add<1>. The decoder 31 also enables one of first to fourth row decoding signals R_dec<0:3>. For example, the decoder 31 enables the first row decoding signal R_dec<0> in the case where the first row address R_add<0> is a low level and the second row address R_add<1> is a low level. The decoder 31 enables the second row decoding signal R_dec<1> where the first row address R_add<0> is the low level and the second row address R_add<1> is a high level. The decoder 31 enables the third row decoding signal R_dec<2> in the case where the first row address R_add<0> is a high level and the second row address R_add<1> is the low level. The decoder 31 enables the fourth row decoding signal R_dec<3> where the first row address R_add<0> is the high level and the second row address R_add<1> is the high level.

The first latch unit 32 enables the first word line WL<0> when the first row decoding signal R_dec<0> is enabled. The first latch unit 32 also retains the enabled first word line WL<0> until the precharge signal PRE is enabled.

The second latch unit 33 enables the second word line WL<1> when the second row decoding signal R_dec<1> is enabled. The second latch unit 33 also retains the enabled second word line WL<1> until the precharge signal PRE is enabled.

The third latch unit 34 enables the third word line WL<2> when the third row decoding signal R_dec<2> is enabled. The third latch unit 34 also retains the enabled third word line WL<2> until the precharge signal PRE is enabled.

The fourth latch unit 35 enables the fourth word line WL<3> when the fourth row decoding signal R_dec<3> is enabled. The fourth latch unit 35 also retains the enabled fourth word line WL<3> until the precharge signal PRE is enabled.

Therefore, the row address decoding block 300 enables corresponding word lines when the first and second row addresses R_add<0:1> with different values are consecutively inputted. The row address decoding block 300 also retains the enabled states until the precharge signal PRE is enabled. For example, when the first and second row addresses R_add<0:1> are inputted both at the low levels and are consecutively inputted both at the high levels, the row address decoding block 300 enables the first word line WL<0> and the fourth word line WL<3> until the precharge signal PRE is enabled.

Referring to FIG. 5, a data select signal generation block 500 (an embodiment of the data select signal generation block 50 shown in FIG. 2), which generates the first and second data select signals D_s<0:1> shown in FIG. 3, includes fifth and sixth latch units 51 and 52 and a selective output unit 53.

The fifth latch unit 51 latches the first row address R_add<0>. The fifth latch unit 51 also outputs the latched signal as a first latch signal L_s<0> and initializes the first latch signal L_s<0> when the precharge signal PRE is enabled. For example, the fifth latch unit 51 enables the first latch signal L_s<0> when the first row address R_add<0> is enabled. Further, the fifth latch unit 51 also retains the enabled first latch signal L_s<0> until the precharge signal PRE is enabled.

The sixth latch unit 52 latches the first row address R_add<0>. The sixth latch unit 52 also outputs the latched signal as a second latch signal L_s<1> and initializes the second latch signal L_s<1> when the precharge signal PRE is enabled. For example, the sixth latch unit 52 enables the second latch signal L_s<1> when the first row address R_add<0> is enabled. In addition, the sixth latch unit 52 retains the enabled second latch signal L_s<1> until the precharge signal PRE is enabled.

The selective output unit 53 outputs the first latch signal L_s<0> as the first data select signal D_s<0> or outputs the second latch signal L_s<1> as the second data select signal D_s<1>, in response to the remainder C_add2 of the column address C_add shown in FIG. 2, excluding the part C_add1 of the column address C_add inputted to the column address decoding block 40. For example, the selective output unit 53 inverts the first latch signal L_s<0> and outputs the first data select signal D_s<0> where the remainder C_add2 of the column address C_add is a low level. The selective output unit 53 also inverts the second latch signal L_s<1> and outputs the second data select signal D_s<1> where the remainder C_add2 of the column address C_add is a high level.

The selective output unit 53 includes first to fourth inverters IV1, IV2, IV3 and IV4 and first and second NAND gates ND1 and ND2. The first inverter IV1 is inputted with the remainder C_add2 of the column address C_add. The second inverter IV2 is inputted with the first latch signal L_s<0>. The first NAND gate ND1 is inputted with the output signal of the first inverter IV1 and the output signal of the second inverter IV2. The third inverter IV2 is inputted with the output signal of the first NAND gate ND1. The third inverter IV2 also outputs the first data select signal D_s<0>. The second NAND gate ND2 is inputted with the remainder C_add2 of the column address C_add and the second latch signal L_s<1>. The fourth inverter IV4 is inputted with the output signal of the second NAND gate ND2. The fourth inverter IV4 also outputs the second data select signal D_s<1>.

Operations of the semiconductor memory apparatus 2000 and the semiconductor system using the same in accordance with an embodiment, configured as mentioned above, will be described below.

Referring again to FIG. 1, the controller 1000 consecutively provides commands CMD, that is, two active commands ACT, two read commands RD or two write commands WT and a precharge command PRE, to the semiconductor memory apparatus 2000. An address ADD is provided to the semiconductor memory apparatus 2000 each time each of the active commands ACT and the read commands RD or the write commands WT is provided to the semiconductor memory apparatus 2000. The controller 1000 exchanges data DATA with the semiconductor memory apparatus 2000.

The semiconductor memory apparatus 2000 inputted with such a command sequence may be configured as shown above in FIG. 2.

The command determination block 10 determines the external command CMD_e inputted from the controller 1000. The command determination block 10 also generates the internal command CMD_i.

The address determination block 20 outputs the address ADD inputted simultaneously with the external command CMD_e, as one of the row address R_add and the column address C_add, in response to the internal command CMD_i. For example, if the internal command CMD_i is the active command ACT, the address determination block 20 outputs the address ADD inputted simultaneously with the active command ACT, as the row address R_add. If the internal command CMD_i is the read command RD or the write command WT, the address determination block 20 outputs the address ADD inputted simultaneously with the read command RD or the write command WT, as the column address C_add.

Describing again the operations of the command determination block 10 and the address determination block 20, when the command CMD inputted from the controller 1000 is the active command ACT, the address ADD inputted simultaneously with the active command ACT is outputted as the row address R_add. If the command CMD inputted from the controller 1000 is the read command RD or the write command WT, the address ADD inputted simultaneously with the read command RD or the write command WT is outputted as the column address C_add.

The row address decoding block 30 decodes the row address R_add. The row address decoding block 30 also selectively enables the word lines WL<0:n>. Since the row address decoding block 30 retains enabled word lines WL<0:n> until the precharge signal PRE is enabled, a plurality of word lines WL<0:n> may be kept enabled together as the row address R_add is consecutively inputted with different values.

The column address decoding block 40 decodes the part C_add1 of the column address C_add. The column address decoding block 40 also selectively enables the column select signals Yi<0:m>.

The data select signal generation block 50 selectively enables the data select signals D_s<0:i> in response to the row address R_add and the remainder C_add2 of the column address C_add.

The data storage region 60 stores or outputs data DATA in or from a position designated by the word lines WL<0:n>, the column select signal Yi and the data select signals D_s<0:i>. For example, the data storage region 60 designates primarily selected positions by the plurality of word lines WL<0:n> enabled together and the column select signal Yi. The data storage region 60 also secondarily selects one position among the primarily selected positions in response to the data select signals D_s<0:i>. Data DATA is inputted or outputted to or from the secondarily selected position.

As a result, the controller 1000 enables together the word lines WL<0:n> of the semiconductor memory apparatus 2000 by consecutively providing an active command ACT and an address ADD. Thereafter, the controller 1000 selectively enables the column select signals Yi<0:m> by consecutively providing a read command RD or a write command WT and an address ADD. Positions to or from which data DATA are to be inputted or outputted are primarily selected according to word lines WL<0:n> which are enabled together and column select signals Yi<0:m> which are enabled. Data DATA is inputted or outputted to or from one position among the primarily selected positions according to the data select signals D_s<0:i>.

Detailed operations of the semiconductor memory apparatus 2000 operating in this way will be described below with reference to FIGS. 3 to 5.

Operations of the row address decoding block 300 (an embodiment of the row address decoding block 30 shown in FIG. 2) will be described below with reference to FIG. 4.

The decoder 31 enables one of the first to fourth row decoding signals R_dec<0:3> in response to the first and second row addresses R_add<0:1>.

The first to fourth latch units 32, 33, 34 and 35 are respectively inputted with the first to fourth row decoding signals R_dec<0:3>. The first to fourth latch units 32, 33, 34 and 35 respectively latch the first to fourth row decoding signals R_dec<0:3>. The first to fourth latch units 32, 33, 34 and 35 also retain latched values until the precharge signal PRE is enabled.

As a result, in the case where the active command ACT is inputted twice and at the same time the first and second row addresses R_add<0:1> are inputted twice, the row address decoding block 300 enables two word lines until the precharge signal PRE is enabled. For example, if the first and second row addresses R_add<0:1> both with the low levels are first inputted and then the first and second row addresses R_add<0:1> both with the high levels are inputted, the row address decoding block 300 retains the enabled first word line WL<0> and fourth word line WL<3> until the precharge signal PRE is enabled.

Referring again to FIG. 3, if both the first and fourth word lines WL<0> and WL<3> are enabled as described above, the first storage region 61 and the second storage region 62 are activated.

The activated first storage region 61 may output or receive data DATA through the first sense amplifier 63. Further, the activated second storage region 62 may output or receive data DATA through the second sense amplifier 64.

If the column select signal Yi is enabled and the first data select signal D_s<0> is enabled, data DATA may be stored in the first storage region 61 or stored data DATA may be outputted, through the first sense amplifier 63.

If the column select signal Yi is enabled and the second data select signal D_s<1> is enabled, data DATA may be stored in the second storage region 62. Alternatively, stored data DATA may be outputted, through the second sense amplifier 64.

A process by which the first and second data select signals D_s<0:1> are generated as described above will be described below with reference to FIG. 5.

The first and second row addresses R_add<0:1> inputted to enable the first word line WL<0> have both the low levels.

The first and second row addresses R_add<0:1> inputted to enable the second word line WL<1> have the low level and the high level, respectively.

The first and second row addresses R_add<0:1> inputted to enable the third word line WL<2> have the high level and the low level, respectively.

The first and second row addresses R_add<0:1> inputted to enable the fourth word line WL<3> have both the high levels.

These may be summarized in a table below as follows.

| WL enable | R_add<0> | R_add<1> |
|---|---|---|
| WL<0> | Low | Low |
| WL<1> | Low | High |
| WL<2> | High | Low |
| WL<3> | High | High |

Referring again to FIG. 3, the first word line WL<0> and the second word line WL<1> are electrically coupled to the first storage region 61. The third word line WL<2> and the fourth word line WL<3> are electrically coupled to the second storage region 62. The first storage region 61 is activated when one of the first and second word lines WL<0:1> is enabled. The second storage region 62 is activated when one of the third and fourth word lines WL<2:3> is enabled.

Referring to the table, the first storage region 61 is activated where the first row address R_add<0> is the low level. Further, the second storage region 62 is activated where the first row address R_add<0> is the high level.

As a result, the case where two active commands ACT are consecutively inputted and both the first and second storage regions 61 and 62 are activated corresponds to the case where the first row address R_add<0> is inputted with the values of the low level and the high level, respectively.

Referring again to FIG. 5, the first row address R_add<0> is latched. The first latch signal L_s<0> is latched as a low level in the case where the first row address R_add<0> is the low level, that is, the first storage region 61 is activated. Further, the first data select signal D_s<0> is enabled to a high level where the remainder C_add2 of the column address C_add is a low level. The second latch signal L_s<1> is latched as a high level in the case where the first row address R_add<0> is the high level, that is, the second storage region 62 is activated. In addition, the second data select signal D_s<1> is enabled to a high level in the case where the remainder C_add2 of the column address C_add is a high level.

Referring again to FIG. 3, where both the first storage region 61 and the second storage region 62 are activated by the two active commands ACT, if both the column select signal Yi and the first data select signal D_s<0> are enabled, data DATA may be stored in or outputted from the first data storage region 61 through the first sense amplifier 63. In addition, where both the first storage region 61 and the second storage region 62 are activated by the two active commands ACT, if both the column select signal Yi and the second data select signal D_s<1> are enabled, data DATA may be stored in or outputted from the second data storage region 62 through the second sense amplifier 64.

Therefore, in the semiconductor memory apparatus in accordance with an embodiment, in the case where two read or write commands are inputted after two consecutive active commands, different storage regions may be activated together and data may be stored or outputted by consecutively executing the read or write commands. While an embodiment shows an example in which the semiconductor memory apparatus is inputted with the same command consecutively twice, it is to be noted that the number of commands consecutively inputted is not limited to two.

In summary, the operation method of the semiconductor system using the semiconductor memory apparatus in accordance with an embodiment is as follows.

The semiconductor system in accordance with an embodiment is constructed by a controller which provides a command and an address and provides data or is inputted with data. The semiconductor system also includes a semiconductor memory apparatus which stores provided data or outputs stored data in response to the command and the address.

The operation method of the semiconductor system may include an active command providing step in which the controller consecutively provides a plurality of active commands to the semiconductor memory apparatus, an operation command providing step in which the controller consecutively provides a plurality of read or write commands to the semiconductor memory apparatus, and a precharge command providing step in which the controller provides a precharge command to the semiconductor memory apparatus.

In the active command providing step, each time each of the plurality of active commands is provided to the semiconductor memory apparatus, an address is provided to the semiconductor memory apparatus.

In the operation command providing step, each time each of the plurality of read or write commands is provided to the semiconductor memory apparatus, an address is provided to the semiconductor memory apparatus.

In the active command providing step, the semiconductor memory apparatus enables together a plurality of word lines in response to the active commands consecutively provided.

In the operation command providing step, the semiconductor memory apparatus sequentially outputs or receives data of positions which are selected by the plurality of word lines enabled together, in response to the respective read or write commands consecutively provided.

In the precharge command providing step, the semiconductor memory apparatus precharges read paths or write paths used by the read or write commands.

While various embodiments have been described above, it will be understood to those skilled in the art that the embodiments described are by way of examples only. Accordingly, the semiconductor memory apparatus and the operating method of a semiconductor system using the same described should not be limited based on the described embodiments above.

1. A semiconductor memory apparatus comprising:
an address determination block configured to output an address as one of a row address and a column address according to an internal command;
a row address decoding block configured to decode the row address and enable a word line;
a column address decoding block configured to decode a partial column address of the column address and enable a column select signal;
a data select signal generation block configured to receive the row address and a remaining column address of the column address and enable a data select signal according to the row address and the remaining column address of the column address; and
a data storage region configured to store or output data according to the word line, the column select signal and the data select signal.

2. The semiconductor memory apparatus according to claim 1,
wherein the address determination block outputs the address as the row address when the internal command is an active command, and
wherein the address determination block outputs the address as the column address when the internal command is a read command or a write command.

3. The semiconductor memory apparatus according to claim 1, wherein the row address decoding block decodes the row address and enables the word line, and retains the enabled word line until a precharge signal is enabled.

4. The semiconductor memory apparatus according to claim 3, wherein the row address decoding block comprises:
a decoder configured to decode the row address and generate a row decoding signal; and
a latch unit configured to enable the word line according to the row decoding signal and the precharge signal.

5. The semiconductor memory apparatus according to claim 1, wherein the data select signal generation block comprises:
a plurality of latch units configured to respectively latch the row address according to the precharge signal, and generate a plurality of latch signals; and
a selective output unit configured to selectively output the plurality of latch signals as the data select signal according to the remaining column address of the column address.

6. The semiconductor memory apparatus according to claim 1, wherein the data storage region comprises:
a storage region configured to be activated in response to the word line;
a sense amplifier electrically coupled with the storage region by a bit line; and
a data selection unit configured to transfer data to the sense amplifier or output an output of the sense amplifier as data when both the column select signal and the data select signal are enabled.

7. The semiconductor memory apparatus according to claim 1, wherein the data storage region comprises:
a first storage region configured to be activated in response to a part of word lines;
a second storage region configured to be activated in response to a remainder of the word lines;
a first sense amplifier electrically coupled with the first storage region by a first bit line;
a second sense amplifier electrically coupled with the second storage region by a second bit line; and
a data selection unit configured to transfer data to one of the first sense amplifier and the second sense amplifier or output an output of one of the first sense amplifier and the second sense amplifier as data in response to the column select signal and the data select signal.

8. An operating method of a semiconductor system including a controller which provides a command and an address and provides data or is inputted with the data, and a semiconductor memory apparatus which stores provided data or outputs stored data in response to the command and the address, the operating method comprising:
an active command providing action in which the controller consecutively provides a plurality of active commands to the semiconductor memory apparatus;
an operation command providing action in which the controller consecutively provides a plurality of read or write commands to the semiconductor memory apparatus; and
a precharge command providing action in which the controller provides a precharge command to the semiconductor memory apparatus,
wherein, in the active command providing action, the semiconductor memory apparatus enables together a plurality of word lines according to the plurality of active commands consecutively provided,
wherein, in the operation command providing action, the semiconductor memory apparatus sequentially outputs or receives data of positions selected by the plurality of word lines enabled together, in response to the plurality of read or write commands consecutively provided,
wherein the semiconductor memory apparatus includes a data select signal generation block that is configured to receive a row address and a remaining column address of the column address and enable a data select signal according to the row address and the remaining column address of the column address,
wherein the data select signal selects data of positions selected by the plurality of word lines enabled together.

9. The operating method according to claim 8, wherein, in the active command providing action, each time each of the plurality of active commands is provided to the semiconductor memory apparatus, an address is provided to the semiconductor memory apparatus.

10. The operating method according to claim 8, wherein, in the operation command providing action, each time each of the plurality of read or write commands is provided to the semiconductor memory apparatus, an address is provided to the semiconductor memory apparatus.

11-12. (canceled)

13. The operating method according to claim 8, wherein, in the precharge command providing action, the semiconductor memory apparatus precharges read paths or write paths used by the plurality of read or write commands.

14. A semiconductor memory apparatus comprising:
a row address decoding block configured to enable together a plurality of word lines according to a row address;
a column address decoding block configured to decode a part of a column address and generate a column select signal;
a data select signal generation block configured to receive the row address and a remaining column address of the column address and generate a data select signal according to the row address and the remainder of the column address; and
a data storage region configured to selectively output a plurality of data selected by the plurality of word lines enabled together and the column select signal enabled according to the data select signal.

15. The semiconductor memory apparatus according to claim 14, wherein the row address decoding block retains the plurality of word lines enabled together in response to the row address until a precharge signal is enabled.

16. The semiconductor memory apparatus according to claim 14, wherein the data select signal generation block latches the row address as a plurality of latch signals until a precharge signal is enabled, and selectively outputs the plurality of latch signals latched, as the data select signal in response to the remainder of the column address.

17. The semiconductor memory apparatus according to claim 14, wherein the data storage region comprises:
a first storage region configured to be activated in response to a part of the plurality of word lines;
a second storage region configured to be activated in response to a remainder of the plurality of word lines;
a first sense amplifier electrically coupled with the first storage region by a first bit line;
a second sense amplifier electrically coupled with the second storage region by a second bit line; and
a data selection unit configured to transfer data to one of the first sense amplifier and the second sense amplifier or output an output of one of the first sense amplifier and the second sense amplifier as the data in response to the column select signal and the data select signal.

18. The semiconductor memory apparatus according to claim 17, wherein the first storage region is activated according to one of a first word line and a second word line.

19. The semiconductor memory apparatus according to claim 18, wherein the second storage region is activated according to one of a third word line and a fourth word line.

20. The semiconductor memory apparatus according to claim 17, wherein when the first storage region is activated, the first sense amplifier is configured to sense and amplify the data transferred through the first bit line and a first bit line bar or to transfer the data to the first storage region.

21. The semiconductor memory apparatus according to claim 20, where when the second storage region is activated, the second sense amplifier is configured to sense and amplify the data transferred through the second bit line and a second bit line bar or to transfer the data to the second storage region.

22. The semiconductor memory apparatus according to claim 17, wherein the data selection unit is configured to transfer the data to the first sense amplifier when the column select signal and a first data select signal are enabled.

23. The semiconductor memory apparatus according to claim 22, wherein the data selection unit is configured to transfer the data to the second sense amplifier when the column select signal and a second data select signal are enabled.

24. The semiconductor memory apparatus according to claim 17, wherein the data selection unit includes a first data selection section configured to transfer the data to the first sense amplifier according to the column select signal and a first data select signal.

25. The semiconductor memory apparatus according to claim 24, wherein the data selection unit includes a second data selection section configured to transfer the data to the second sense amplifier according to the column select signal and a second data select signal.
